(19) United States
(12) Patent Application Publication
(10) Pub. No.: US 2026/0235702 A1
(43) Pub. Date: Aug. 13, 2026

(54) CONNECTOR MATING DETERMINATION SYSTEM

(71) Applicant: TOYOTA JIDOSHA KABUSHIKI KAISHA, Toyota-shi (JP)

(72) Inventors: Tomohiro MATSUDA, Toyota-shi (JP); Kenji OJIMA, Nagoya-shi (JP); Tomohiro TSUBOTA, Nagoya-shi (JP)

(73) Assignee: TOYOTA JIDOSHA KABUSHIKI KAISHA, Toyota-shi (JP)

(21) Appl. No.: 19/448,363

(22) Filed: Jan. 14, 2026

(30) Foreign Application Priority Data
Feb. 7, 2025 (JP) 2025-019295

(51) Int. Cl. G01R 31/58; G01H 1/00

(52) U.S. Cl. CPC G01R 31/58; G01H 1/00

(57) ABSTRACT

Actual data of a physical quantity corresponding to a mating operation of the connector is acquired, and a determination unit is adjusted to be configured to determine whether a mating state of a first type connector of at least two types of connectors is normal by using the actual data of the first type connector as reference data. Then, corrected data obtained by correcting the actual data acquired in a mating operation of a second type connector other than the first type connector in accordance with the reference data is output, and a determination execution unit determines whether a mating state of the second type connector is appropriate by inputting the output corrected data to the determination unit.

### CROSS-REFERENCE TO RELATED APPLICATION

This application claims priority to Japanese Patent Application No. 2025-019295 filed on Feb. 7, 2025. The disclosure of the above-identified application, including the specification, drawings, and claims, is incorporated by reference herein in its entirety.

### BACKGROUND

### 1. Technical Field

The present disclosure relates to a technique of determining whether a mating state of a connector is appropriate.

### 2. Description of Related Art

In recent years, various methods of supporting work of a worker in a manufacturing process of a product have been proposed. For example, Japanese Unexamined Patent Application Publication No. 2006-221971 (JP 2006-221971 A) discloses a system that determines whether a connector in an electrical component is mated appropriately.

### SUMMARY

However, in the system of JP 2006-221971 A, reference data that is data of vibration needs to be prepared in a case of being appropriately mated for each combination of connectors to be mated. In this case, there is a problem that an amount of labor for preparing the reference data increases as the number of types of connectors increases.

The present disclosure can be implemented as the following aspects or applications.

(1) The present disclosure relates to a connector mating determination system that determines a mating state of at least two types of connectors. The connector mating determination system includes
an acquisition unit configured to acquire actual data of a physical quantity corresponding to a mating operation of the connector,
a determination unit adjusted to be configured to determine whether a mating state of a first type connector of the at least two types of connectors is normal by using the actual data of the first type connector as reference data,
a correction unit configured to output corrected data obtained by correcting the actual data acquired in a mating operation of a second type connector other than the first type connector in accordance with the reference data, and
a determination execution unit configured to determine whether a mating state of the second type connector is appropriate by inputting the corrected data to the determination unit.

According to the connector mating determination system, the determination unit that determines whether to mate for each of a plurality of the second type connectors is not necessary to be prepared.

(2) In the configuration of (1), the connector mating determination system may further include an identification unit configured to identify whether a connector that is a target of a determination of the mating state is the first type connector or the second type connector of the at least two types. In this manner, it is possible to easily determine whether to mate the both connectors.

(3) In the configuration of (2), the identification unit may include a wearable camera worn by a worker, and perform the identification of the connector by an image captured by the wearable camera. In this manner, it is possible to easily identify the connector.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of a connector mating determination system of a first embodiment;

FIG. 2 is an explanatory diagram showing actual data in a case of mating a connector;

FIG. 3 is an explanatory diagram showing a difference in actual data in a case of mating a plurality of types of connectors;

FIG. 4 is a flowchart showing a correction coefficient calculation processing routine;

FIG. 5 is a flowchart showing processing of determining whether to mate the connector; and

FIG. 6 is an explanatory diagram showing a state of correcting the actual data of the connector that is a determination target.

### DETAILED DESCRIPTION OF EMBODIMENTS

### A. First Embodiment

### A1. Device Configuration:

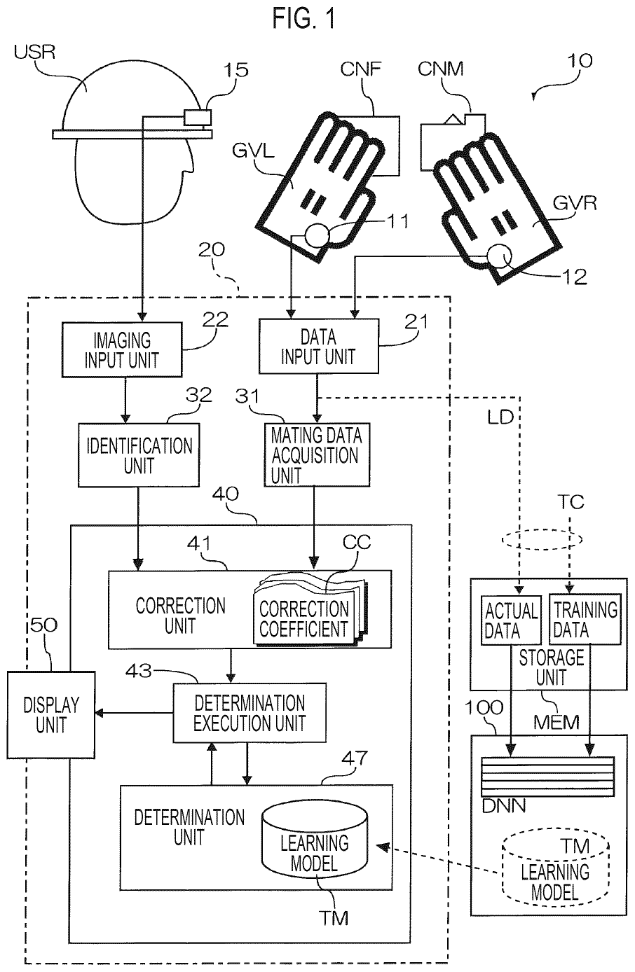

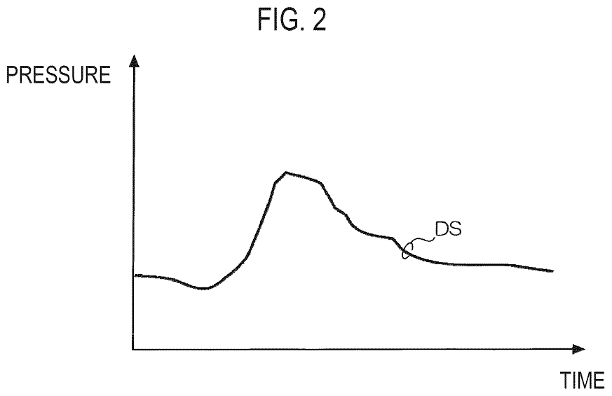

FIG. 1 is a schematic configuration diagram of a connector mating determination system 10 according to the embodiment. FIG. 2 shows a connector mating determination device 20 that determines whether to mate the connector, and a learning device 100 that provides a learning model for the determination in the connector mating determination device 20. The learning model TM is trained by the learning device 100 before the determination by the connector mating determination device 20. The learning of the learning model TM and the like will be described later.

The connector mating determination system 10 includes the connector mating determination device 20, pressure sensors 11, 12 connected to the connector mating determination device 20, and a wearable camera 15 mounted on a head of a user USR or the like. The pressure sensor 11 is provided in each of a pair of gloves GVL, GVR that are worn by both hands of the user USR. The pressure sensors 11, 12 detect vibration generated in conjunction with the mating of a connector CNF held by the user USR with the glove GVL of a left hand and a connector CNM held with the glove GVR of a right hand as a pressure change. The pressure sensors 11, 12 may be provided in only one of the gloves. In addition, in the present embodiment, the connector CNF held with the left hand and the connector CNM held with the right hand have a female-male relationship, and both the connectors CNF, CNM are provided with a ratchet for preventing detachment. Therefore, in a case where the both are mated, vibration (pressure change) occurs not only by bonding of metallic pins that are electrically conductive but also by meshing of the ratchets of the synthetic resin forming the connector body.

The wearable camera 15 mounted on the head of the user USR constantly images a vicinity of a hand of the user USR that mates the connector basically in a visual line direction of the user USR. It goes without saying that a fixed camera fixed to a ceiling, a wall surface, or the like of a work site may be used as long as the vicinity of the hand of the user USR, that is, the vicinity of the gloves GVL, GVR can be imaged. In addition, the imaging does not need to be performed constantly, and the imaging may be performed in response to an instruction from the user USR at a start of the work of mating the connector, or may be performed intermittently, such as every 1 second.

As shown in the drawing, the connector mating determination device 20 includes: a data input unit 21 that receives a signal from the pressure sensors 11, 12; an imaging input unit 22 that receives a video signal from the wearable camera 15; a mating data acquisition unit 31 that receives actual data LD from the data input unit 21; an identification unit 32 that receives an image signal from the imaging input unit 22 and identifies the connector; and a determination control unit 40 that determines the mating state of the connector.

The determination control unit 40 at least further includes: a correction unit 41 that corrects the mating data by using a correction coefficient CC prepared in advance for each type of the connector; a determination execution unit 43 that causes a determination unit 47 to perform the determination by using the corrected mating data and determines whether to mate the connector; and a display unit 50 that displays a result of the determination. The determination unit 47 that performs the determination in response to an instruction from the determination execution unit 43 includes the learning model TM that is trained by machine learning by the learning device 100 described below, and determines the mating state of the connector by using the corrected mating data and the learning model TM. The determination control unit 40 includes at least one CPU and can be realized as an arithmetic logic operation circuit that realizes the correction unit 41, the determination execution unit 43, the determination unit 47, and the like by executing a program prepared in advance. The determination control unit 40 includes a memory and can store the correction coefficient CC, the learning model TM, and the like described below.

### A2. Training of Learning Model TM:

The machine learning of the learning model TM is performed by the learning device 100. For convenience of drawing, the learning device 100 is shown in FIG. 1 together with the connector mating determination device 20, but the learning device 100 is prepared before the work of mating the connectors CNF, CNM, and performs the machine learning of the learning model TM. As shown in the drawing, the learning device 100 includes a deep neural network (DNN) that performs the machine learning. The learning device 100 performs deep learning using a large amount of actual data LD and training data TC of whether to mate the connector corresponding to the actual data LD before determining whether to actually mate the connector. An example of the actual data LD used for the learning is shown in FIG. 2. As shown in the drawing, in the present embodiment, the actual data LD is data of a time change in pressure detected by the pressure sensors 11, 12. In the drawing, the data is shown as a waveform DS of the actual data LD of the connector (hereinafter, referred to as a target connector) that is a target of the learning. Since the change in pressure detected by the pressure sensors 11, 12 is substantially the same, any one of the pressure sensors 11, 12 may be used, or an arithmetic mean value, a weighted average value, or the like of the detection values of both the pressure sensors 11, 12 may be used. In addition, an acoustic sensor or the like may be used instead of the pressure sensor.

In a case of acquiring the actual data LD for learning, the following may be included in the configuration shown in the drawing: the gloves GVL, GVR on which the pressure sensors 11, 12 are mounted; the data input unit 21 that receives the data from the pressure sensors 11, 12; and a storage unit MEM that stores the actual data LD. The user USR repeats the mating of one type of the connector to collect the actual data LD, and determines in advance whether the mating state of the connector is normal or not normal in a case where each actual data LD is collected. Then, the user USR stores the determination result as the training data TC in the storage unit MEM in association with each actual data LD.

The collection of the actual data LD and the creation of the training data TC for the one type of the connector may be performed by the user USR, or may be performed by a person different from the user USR. In addition, the gloves GVL, GVR, the pressure sensors 11, 12, or the like used in the collection of the actual data LD may be the same as those used in the determination of the mating state of the connector. The gloves or the pressure sensors used in the collection of the actual data LD and the gloves or the pressure sensors used in the determination of the mating state of the connector may be different from each other as long as the characteristics are the same or approximate.

The learning device 100 reads a large amount of each actual data LD and the training data TC associated with the actual data LD, and generates the learning model TM by learning using the DNN. The generated learning model TM is transmitted to the determination unit 47 of the connector mating determination device 20 and is used to determine the mating state of the connector. The learning model TM is created for one type of the connector, but in an examination of the actual mating state of the connector, the determination of whether the mating state is appropriate is performed for a plurality of types of the connectors. In this case, the connector that is a target of the determination of whether the mating state is appropriate includes not only the connector that is the same as the connector that is trained by using the training data TC but also a connector that is not the same but is similar. For example, the following connectors are assumed as the similar connectors: a connector having the same mating structure as a certain type of target connector but having a different size; a connector having the same structure and size as a certain type of target connector but having a different specification (for example, a waterproof connector with respect to a standard connector); a connector having a different shape or a different material used for molding from a certain type of target connector; and a connector having the same shape of a portion that is mated during the mating as a certain type of target connector but having at least one different dimension of three-dimensional dimensions of the connector.

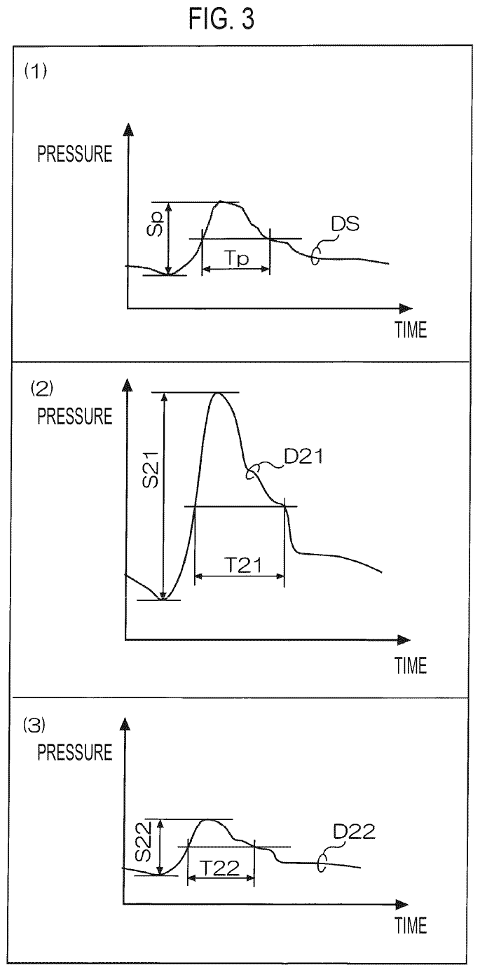

An example of a difference in the actual data LD in the connectors of such different types is shown in FIG. 3. In the drawing, (1) shows the waveform DS of the actual data LD in a case of the target connector used for training the learning model TM. On the other hand, (2) shows a waveform D21 of the actual data LD of a connector of the same type as the target connector and having a waterproof specification. In addition, (3) shows a waveform D22 of the actual data LD of a connector of the same type as the target connector and having the same mating structure but having a smaller shape than the target connector. Here, the target connector of the waveform DS corresponds to the first type connector, and the connector of the waveform D21 or the waveform D22 corresponds to the second type connector. In this case, the learning of the learning model TM is performed using only a plurality of pieces of the actual data LD corresponding to the waveform DS.

There may be a certain type of connector, a waterproof connector of the same type as the connector, a small connector of the same type as the connector, and the like. Hereinafter, a set of the connectors is referred to as a connector group. The learning model TM using the actual data LD of the waveform DS is trained for each connector group. In a case where there is one connector group, one learning model is generated. On the other hand, in a case where there is a plurality of connector groups, the learning model TM may be prepared for each connector group by performing the learning using the target connector (first type connector) that represents each of the connector groups. In addition, in a case where there is a plurality of connector groups, the learning may be performed such that the learning model TM can determine whether the mating state of the target connector representing the connector groups is appropriate.

### A3. Calculation of Correction Coefficient:

Next, the calculation of the correction coefficient will be described. As described above, each of the connectors included in the connector group has different actual data LD as shown in FIG. 3. Therefore, one of the connectors belonging to the connector group is treated as the first type connector, and the actual data LD of the first type connector is referred to as reference data. Among the connectors belonging to the connector group, a connector other than the standard connector is referred to as a second type connector. In a case where the mating state of the second type connector is determined by using the learning model TM, the determination is performed after the actual data LD is corrected to the corrected data by using the correction coefficient.

The correction coefficient used in this case is obtained in advance for each second type connector and is stored in the correction unit 41 of the determination control unit 40. The correction coefficient CC is calculated by measuring the actual data LD for the first type connector and the actual data LD for the second type connector in advance and inputting the measured data to a computer. Any computer that can handle the actual data LD along the time axis can be used. For example, the calculation may be executed by the determination control unit 40 of the connector mating determination system 10.

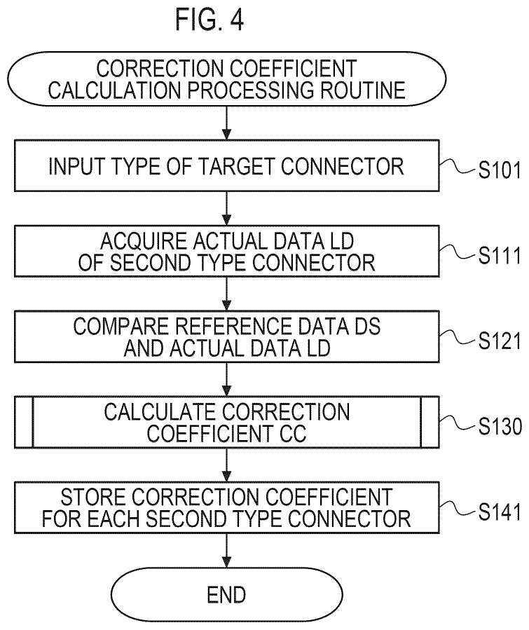

An example of a correction coefficient calculation processing routine for obtaining the correction coefficient CC by the computer is shown in FIG. 4. The processing routine is executed for the second type connectors belonging to one connector group. Before the processing is executed, the reference data DS of the first type connector is input and stored in a memory or the like. In a case where the processing routine is started, first, a type of the second type connector that is a target of obtaining the correction coefficient CC is input (S101). For example, a type of the connector belonging to the second type connector, such as a “waterproof connector” or a “small connector”, is input. The type may be identified by a unique symbol as long as the difference between the second type connectors is identified. The type may be input as text representing a feature of the second type connector, such as a specification purpose or a shape, as in the example, or may be input as a number such as No. 101 or No. 201.

Next, the actual data LD of the second type connector of which the type is input is input (S111). The actual data LD may be obtained by actually mating the connector each time and reading the data from the pressure sensors 11, 12 in this case, or may be obtained by reading the data acquired and stored in advance. Hereinafter, for example, the actual data LD is referred to as waveform data D21 in the waterproof connector shown in (2) of FIG. 3, and is referred to as waveform data D22 in the small connector shown in (3) of FIG. 3. In a case where the type of the connector is not limited, the actual data LD may be referred to as waveform data LD.

In a case where the actual data LD for each second type connector is input in this way, the waveform data D21, D22, and the like and the waveform DS of the reference data are compared (S121). In the comparison, at least the height of the peak of each waveform is compared. In addition, a time from a rise to a fall of the waveform may also be compared. Based on the comparison between the two, next, processing of obtaining the correction coefficient CC is performed (S130). The correction coefficient CC is obtained as, for example, the following Expression (1) in a case where the actual data LD of the second type connector x is the waveform data D(x) with respect to the reference data DS of the first type connector.

$$CC ( x ) = DS / D ( x ) \qquad ( 1 )$$

Since the actual data is a pressure change along the time axis, the correction coefficient CC(x) for the connector x is represented by a wave height value of the pressure change or a pulse width of the pressure change. The correction coefficient CCp(x) focusing on the wave height value of the pressure change for the connector x is represented by the following Expression (2).

$$CCp ( x ) = Sx / Sp \qquad ( 2 )$$

Here, the value Sp is a peak value of the pressure of the reference data DS obtained from the first type connector, and the value Sx is a pressure peak value of the waveform data Dx of the second type connector x.

Similarly, it is also possible to obtain the correction coefficient by focusing on a pulse width T of the actual data of the pressure change. The correction coefficient CCt(x) focusing on the pulse width of the pressure change for the connector x is represented by the following Expression (3).

$$CCt ( x ) = Tx / Tp \qquad ( 3 )$$

Here, the value Tp is a pulse width of the pressure change of the reference data DS obtained from the first type connector, and the value Tx is a pulse width of the pressure change of the waveform data Dx of the second type connector x. As described above, the time from the rise to the fall of the waveform may be defined as a so-called half-width in which a magnitude of the signal is ½ of the peak. It may be defined according to other definitions.

As shown in (2) of FIG. 3, in a case where a wave height value of the waveform data D21 of the waterproof connector (2), which is one of the second type connectors, is a value S21 and a wave height value of the waveform data D22 of the small connector (3), which is the other of the second type connectors, is a value S22, each correction coefficient CCp(x) is as follows.
CCp(2)=Sp/S21,
CCp(3)=Sp/S22. The correction coefficient can also be obtained in the same manner for the pulse width of the data of the pressure change.

As described above, the correction coefficient CC need only be obtained for at least the wave height value of the pressure for one second type connector x. As shown in the drawing, the wave height value may be treated as a peak value or may be treated as an average value of the pressure. After the correction coefficient CC(x) is obtained, the obtained correction coefficient CC(x) is stored in the correction unit 41 for each type of the second type connector (S141). The correction coefficient calculation processing routine ends.

### A4. Processing of Determining Whether to Mate Connector:

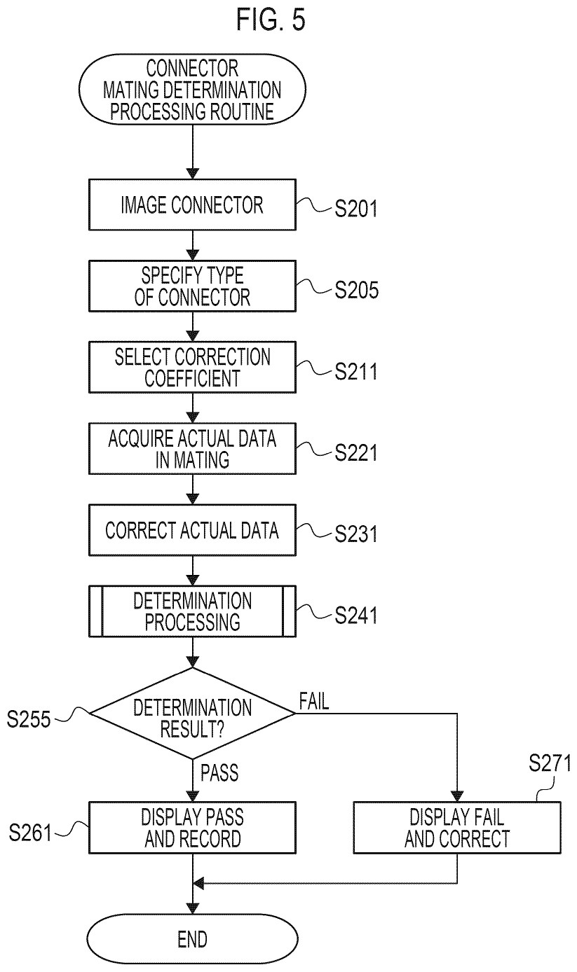

After the preparation, next, processing of determining whether to mate the connector, which is performed by the connector mating determination system 10, will be described. FIG. 5 is a flowchart showing an example of a connector mating determination processing routine. The processing is executed by the connector mating determination device 20 in a case where the user USR wears the gloves GVR, GVL and mates the connectors CNF, CNM.

In a case where the processing is started, first, the connector is imaged by using the wearable camera 15 (S201). The wearable camera 15 is mounted on the head of the user USR and basically images a range that is directly viewed by the user USR. That is, an image in the visual line of the user USR, that is, a so-called first-person image is captured by the wearable camera 15. Therefore, processing of specifying the type of the connectors CNF, CNM that the user USR is trying to mate and is holding is performed from the image captured by using the wearable camera 15 (S205). In this case, in a case where the connectors CNF, CNM that are to be mated are not shown in the image captured by the wearable camera 15 or the captured image is unclear, the imaging by the wearable camera 15 may be performed again. In a case where the connectors CNF, CNM are shown but the type of the connector cannot be specified, an error may be displayed on the display unit 50 and the work may be stopped because it is not possible to determine whether to mate the connector.

In a case where the type of the connector can be specified, next, the correction coefficient corresponding to the identified type of the connector is selected (S211). In the embodiment, the correction coefficient is obtained by focusing on the wave height value of the pressure change and is stored in the correction unit 41. Subsequently, the pressure change detected by the pressure sensors 11, 12 is acquired as the actual data LD in the mating (S221), and the actual data LD is corrected by using the correction coefficient CC(x) selected in S211 (S231).

As already described, the correction coefficient CC(x) is obtained by Expression (1). In the present embodiment, the correction coefficient is obtained for the wave height value. Therefore, the corrected data after the correction obtained by correcting the actual data LD by the correction coefficient CC(x) is data in which the actual data LD in the mating is corrected such that the wave height value is Sp/Sx without changing the width in the time axis direction. In a case where the wave height value of the waveform data D21 is larger than the reference data DS as in the waterproof connector, the wave height value of the corrected data Da21, which is the corrected waveform data, is reduced. In a case where the wave height value of the waveform data D22 is smaller than the reference data DS as in the small connector, the wave height value of the corrected data Da22 after the correction is increased.

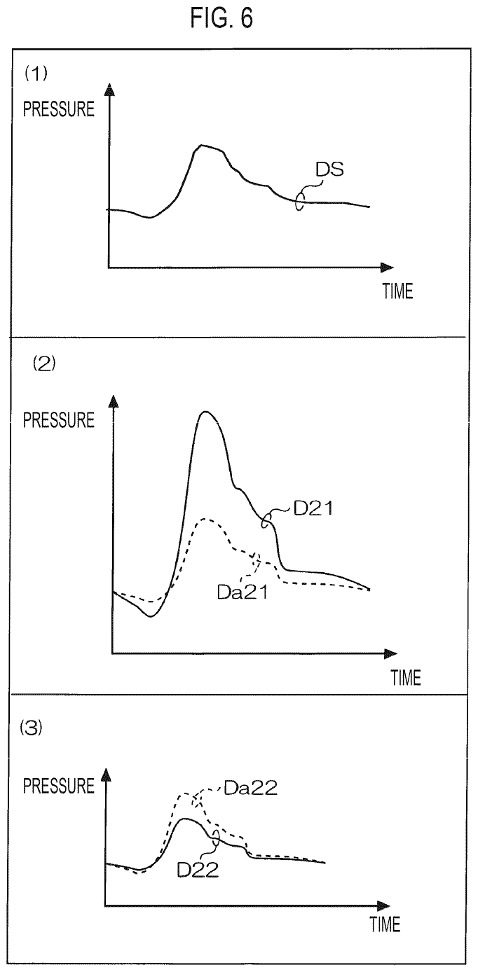

The state of the correction is shown in FIG. 6. In the drawing, the solid line indicates the waveform data acquired in the mating, and the broken line indicates the corrected data after the correction by the correction coefficient. (1) in the drawing is the reference data DS shown for comparison. (2) is an example of the waterproof connector, and the corrected data Da21 obtained by correcting the waveform data D21 by using the correction coefficient CCp(2) has a reduced overall wave height value. (3) in the drawing is an example of the small connector, and the corrected data Da22 obtained by correcting the waveform data D22 by using the correction coefficient CCp(3) has an increased overall wave height value. As a result, the corrected data approaches the reference data DS of the first type connector of (1) shown in the drawing, regardless of whether the second type connector is the waterproof connector or the small connector.

After the acquisition (S221) of the actual data of the pressure change for the connector that the user USR is mating and the correction (S231) based on the type of the connector are performed in this way, the determination processing of whether to mate is performed (S241). Whether the connectors CNF, CNM are appropriately mated, that is, normally mated is performed by using the learning model TM prepared in the determination unit 47 by using the corrected data. As already described, the learning model TM is generated by training the DNN using a large amount of actual data LD in the mating and the training data TC representing whether to mate. Therefore, the determination execution unit 43 can receive the determination result of whether the connectors are appropriately mated from the determination unit 47 by outputting the data of the pressure change in the mating, which is corrected by using the correction coefficient CC(x), to the determination unit 47.

Therefore, in a case where the determination unit 47 determines that the mating is appropriately performed (S255), the mating between the connectors is determined to be “pass”, “pass” is displayed on the display unit 50, and the determination is recorded (S261). The record includes data to the extent that the situation in the mating can be tracked later, such as the type of the connector, the acquired actual data LD, a serial number of the product in which the connector is used, a date and time at which the mating of the connector is performed, and a symbol for specifying the user USR. It goes without saying that a part or all of such data need not be recorded as necessary. For example, a printer or a marking device is provided instead of the display unit 50 or together with the display unit 50, and a seal on which “pass (date, person in charge)” or the like is printed can be output. Then, the obtained label may be attached to or marked on the connector or the like.

On the other hand, in a case where the determination cannot be made that the mating of the connector is appropriate by the determination processing (S241) (S255), the mating between the connectors is determined to be “fail”. Then, “fail” is displayed on the display unit 50, and a correction instruction to mate the connector again is displayed (S271). Various factors are considered for the failure of the mating. Examples of the factor include a case where the work of mating the connector is inappropriate and the engagement of the engaging portion provided in the connector is not sufficiently performed; a case where the sufficient mating is not performed due to a dimensional defect of the connector itself; and a case where the way in which the user USR holds the connector is not in accordance with the manual or the like and the actual data LD is not appropriately acquired from the pressure sensor 11 or the like. Therefore, for the connector determined to be “fail”, the malfunctioning product may be separately treated without performing the mating processing again, the correction processing, or the like, and may be treated by a specialized department such as a malfunction analysis team to analyze the factor that caused the failure and to respond to the factor. After the processing, the present processing routine ends by exiting to “END”.

### A5. Operation and Effect of Embodiment:

According to the connector mating determination system 10 of the embodiment described above, it is possible to easily determine whether to mate the plurality of second type connectors belonging to one connector group. For each of the second type connectors, the waveform data of the pressure change acquired by the pressure sensors 11, 12 is different, but the determination of whether to mate is performed after correcting the different data. Therefore, it is not necessary to prepare a plurality of models to determine whether to mate by directly using the data of the pressure change. In a case where machine learning such as deep learning is used to determine whether to mate, it takes time and effort to form the learning model, so that the advantage is particularly large.

As described above, the number of the connector groups is one, but the determination of whether to mate may be performed for a plurality of the connector groups. In that case, in each connector group, an individual correction coefficient may be used. In addition, the correction is performed by linearly correcting the magnitude of the actual waveform data LD of the second type connector by the wave height value or the pulse width of the pressure, but the correction coefficient itself may be trained by machine learning using a large amount of actual data to generate a learning model for correction. In a case where the actual data is input to the input layer of the learning model for correction that is trained in this way, the corrected data that is close to the reference data is output to the output layer of the learning model.

### B. Other Embodiments

(1) As another embodiment, a connector mating determination system that determines a mating state of at least two types of connectors can be used. The connector mating determination system includes: an acquisition unit configured to acquire actual data of a physical quantity corresponding to a mating operation of the connector; a determination unit adjusted to be configured to determine whether a mating state of a first type connector of the at least two types of connectors is normal by using the actual data of the first type connector as reference data; a correction unit configured to output corrected data obtained by correcting the actual data acquired in a mating operation of a second type connector other than the first type connector in accordance with the reference data; and a determination execution unit configured to determine whether a mating state of the second type connector is appropriate by inputting the corrected data to the determination unit. The connector mating determination system can be implemented in various aspects as follows.

(2) In the configuration, the correction unit may output the corrected data that is in accordance with the reference data by multiplying the actual data by a correction coefficient prepared according to the type of the connector. The actual data is data acquired in the mating operation of the second type connector. In this manner, the corrected data can be obtained by a simple process. The correction coefficient may be prepared for one or a plurality of physical quantities.

In the configuration, the correction unit may include a learning model that has been trained in advance on a relationship between the actual data and the reference data, and may output the corrected data by using the learning model in response to the input of the actual data. The actual data is data acquired in the mating operation of the second type connector. In this manner, the correction that brings the corrected data closer to the reference data can be performed instead of the correction by the linear correction coefficient.

(3) In the configuration, the acquisition unit may be at least one of
[1] an acoustic sensor that detects a sound in a case of mating the connector,
[2] a first vibration sensor that is provided in a glove of a worker who mates the connector and detects vibration,
[3] a second vibration sensor that is provided in a machine that mates the connector and detects vibration, or
[4] a speed sensor that detects a change in a relative movement speed of the connector to be mated. In this manner, an appropriate sensor can be selected from various sensors to acquire the physical quantity. As the acoustic sensor, a general-purpose sensor such as a microphone or a piezoelectric element can be used. As the vibration sensor, not only the piezoelectric element but also a semiconductor type vibration sensor can be used. In a case where a person (worker) performs the work of mating the connector, the vibration sensor may be provided in a glove of the worker or may be provided in a wristband, a ring to be fitted to a finger, or the like. In addition, in a case where the work of mating is performed by a machine such as a robot, various sensors may be provided in the machine such as the robot, a workbench, or the like.

(4) In the configuration, the determination unit may determine whether to mate the connector by using a trained model that has been trained by machine learning using the actual data. In this manner, the determination unit can be easily configured by machine learning. It goes without saying that the determination of whether to mate may be performed by using a technique such as dynamic pattern matching from the similarity of the outputs of the pressure sensor or the like without using the machine-learned learning model.

(5) In the configuration, the determination execution unit may be configured as follows in a case where the connector is identified as the first type connector. That is, the determination execution unit may cause the determination unit to determine the data equivalent to the actual data of the physical quantity corresponding to the mating operation of the connector as the corrected data. In this manner, it is not necessary to prepare a special determination unit for the first type connector.

(6) In addition, the present disclosure can be implemented as a mating determination method of determining a mating state of at least two types of connectors. In the mating determination method, first, actual data of a physical quantity corresponding to the mating operation of the connector is acquired. Then, the determination unit is adjusted such that it is possible to determine whether the mating state of the first type connector is normal by using the actual data of the first type connector of the at least two types of connectors as reference data. The corrected data obtained by correcting the actual data acquired in the mating operation of the second type connector other than the first type connector in accordance with the reference data is output. Then, the determination execution unit determines whether the mating state of the second type connector is appropriate by inputting the output corrected data to the determination unit. In this manner, it is possible to easily determine whether to mate the plurality of connectors.

(7) In each of the embodiments, a part of the configuration realized by hardware may be replaced with software. At least a part of the configuration realized by software can also be realized by a discrete circuit configuration. In addition, in a case where a part or all of the functions of the present disclosure are realized by software, the software (computer program) can be provided in a form of being stored in a computer-readable recording medium. The “computer-readable recording medium” is not limited to a portable recording medium such as a flexible disk or a CD-ROM. The “computer-readable recording medium” also includes an internal storage device in a computer, such as various RAMs and ROMs, and an external storage device fixed to a computer, such as a hard disk. That is, the “computer-readable recording medium” has a broad meaning including any recording medium that can fix a data packet not temporarily.

The present disclosure is not limited to the embodiments, and can be implemented with various configurations without departing from the gist of the present disclosure. For example, the technical features in the embodiment corresponding to the technical features in each aspect described in the summary of the disclosure can be appropriately replaced or combined. In a case where the technical features are not described as being always needed in the present specification, the features can be deleted as appropriate.

What is claimed is:

1. A connector mating determination system that determines a mating state of at least two types of connectors, the connector mating determination system comprising:
an acquisition unit configured to acquire actual data of a physical quantity corresponding to a mating operation of the connector;
a determination unit adjusted to be configured to determine whether a mating state of a first type connector of the at least two types of connectors is normal by using the actual data of the first type connector as reference data;
a correction unit configured to output corrected data obtained by correcting the actual data acquired in a mating operation of a second type connector other than the first type connector in accordance with the reference data; and
a determination execution unit configured to determine whether a mating state of the second type connector is appropriate by inputting the corrected data to the determination unit.

2. The connector mating determination system according to claim 1, further comprising an identification unit configured to identify whether a connector that is a target of a determination of the mating state is the first type connector or the second type connector of the at least two types.

3. The connector mating determination system according to claim 2, wherein the identification unit includes a wearable camera worn by a worker, and performs the identification by an image captured by the wearable camera.
